(19) United States
(12) Patent Application Publication
(10) Pub. No.: US 2025/0285807 A1
(43) Pub. Date: Sep. 11, 2025

(54) ELECTRICAL DEVICE COMPRISING A CAPACITOR WITH AN IMPROVED DIELECTRIC STRUCTURE

(71) Applicant: Murata Manufacturing Co., Ltd., Nagaokakyo-shi (JP)

(72) Inventors: Larry BUFFLE, Grenoble (FR); Valentin SALLAZ, Grenoble (FR); Frédéric VOIRON, Barraux (FR)

(21) Appl. No.: 19/076,341

(22) Filed: Mar. 11, 2025

(30) Foreign Application Priority Data
Mar. 11, 2024 (EP) 24305366.7

(51) Int. Cl. H01G 4/12; H01G 4/005; H01G 4/30

(52) U.S. Cl. CPC H01G 4/1209; H01G 4/005; H01G 4/306

(57) ABSTRACT

An electrical device that includes: a capacitor including: a cathode, an anode, and a dielectric structure interposed between the cathode and the anode, wherein the dielectric structure includes a stack of dielectric layers including: a dielectric layer in contact with the cathode, and one or more other dielectric layers, and wherein a product of a dielectric strength (E_{crit}¹²¹) and a permittivity (εᵣ¹²¹) of the dielectric layer in contact with the cathode is greater than a product of a dielectric strength (E_{crit}¹²², E_{crit}¹²³) and a permittivity (εᵣ¹²², εᵣ¹²³) of each of the one or more other dielectric layers.

### CROSS REFERENCE TO RELATED APPLICATIONS

The present application claims priority to European Patent Application No. EP24305366.7, filed Mar. 11, 2025, the entire contents of which is incorporated herein by reference.

### FIELD OF THE DISCLOSURE

The present disclosure relates to the field of electrical devices. More particularly, it relates to an electrical device comprising a capacitor and a method for manufacturing thereof. The present disclosure is particularly advantageous for implementing capacitors for high voltage applications, but such an application is only given as an illustrative example and does not limit the disclosure.

### DESCRIPTION OF RELATED ART

The present disclosure lies within the particular context of three-dimensional (3D) capacitors for high voltage applications, but is not limited to this particular context.

Capacitors with 3D capacitive structures have been developed in view of providing high energy storage density. Typically, such 3D capacitive structures are formed conformally on reliefs (e.g., pores, holes, trenches, or pillars) and provide a large specific area for a given component size. Still, capacitors with 3D structures cannot be directly transposed to high voltage applications (e.g., exceeding 900 V, or 1,200 V) without considering the specific features and constraints of these applications.

In particular to withstand high voltages, 3D capacitive structures with significantly thicker dielectric structures are used (e.g., dielectric structures thicker than 500 nm, or even 1,000 nm). It is also known to use multi-layer dielectric structures for high voltage applications. This allows adjusting the properties of the dielectric structure including its dielectric strength, mechanical stress, and adherence to the capacitor electrodes. Thick and multi-layer dielectric structures are used to achieve high dielectric strength in order to increase the breakdown voltage and ensure reliable operation at high voltages.

However, the use of particularly thick dielectric structures induces significant mechanical stress within the capacitive structure. This mechanical stress can result in cracks in the dielectric structure and hence a deterioration of its electrical properties, including a reduction in its dielectric strength and an increase in leakage current. This negatively impacts the breakdown voltage and reliability of the capacitor.

Therefore, there is a need for an electrical device comprising a capacitor with an improved dielectric structure capable of reliably withstanding high voltages.

### SUMMARY OF THE DISCLOSURE

The present disclosure has been made in light of the above problems.

According to an aspect, the present disclosure provides an electrical device comprising a capacitor including: a cathode capacitor electrode, an anode capacitor electrode, and a dielectric structure interposed between the cathode capacitor electrode and the anode capacitor electrode, wherein the dielectric structure comprises a stack of dielectric layers including: a dielectric layer in contact with the cathode capacitor electrode, and one or more other dielectric layers, and wherein a product of a dielectric strength and a permittivity of the dielectric layer in contact with the cathode capacitor electrode is greater than a product of a dielectric strength and a permittivity of each of said one or more other dielectric layers.

The present disclosure relates to an electrical device comprising a polarized capacitor which includes a cathode and an anode. The polarized capacitor is intended to be used according to a specific polarity in which the cathode is the negatively charged electrode of the capacitor and the anode is the positively charged electrode of the capacitor. When the polarized capacitor is used according to the proper polarity (cathode negatively charged and anode positively charged), the electrical performance of the capacitor is enhanced (compared with the use of the capacitor according to the improper polarity), and in particular its breakdown voltage.

Hereinafter, the expression “dielectric strength of a dielectric layer” (also known as dielectric rigidity) is used to refer to the maximum electrical field E_{crit} that the dielectric layer can withstand without undergoing electrical breakdown. The expression “permittivity of a dielectric layer” is also used to refer to either the relative permittivity εᵣ of the dielectric layer or the absolute permittivity. In the present disclosure, the relative permittivity εᵣ is used for the sake of convenience, but the person skilled in the art will be able to substitute relative permittivity values with absolute permittivity values if needed.

The present disclosure proposes using a multilayer dielectric structure (said stack of dielectric layers that are stacked in the direction anode-cathode) wherein the dielectric layer with the highest figure of merit E_{crit}×εᵣ is placed in contact with the cathode. This allows significantly improving the dielectric performance of the dielectric structure for the following reasons (these reasons are further detailed below in reference to the figures).

First, we consider a single dielectric layer. For a single layer, the Selbeherr's model links the effective breakdown of the layer to: (a) the leakage current (i.e., the current density |\vec{Jₙ}|) driven by the electrical field E_{field} applied to the layer, and (b) the dielectric strength E_{crit} of the layer. From the Selberherr's model, it follows that a dielectric layer achieves a higher breakdown when the ratio E_{crit}/E_{field} is increased for this dielectric layer.

Second, we consider a dielectric structure with a stack of multiple dielectric layers. With such dielectric structure, it can be shown that the dielectric layer with the highest ratio E_{crit}/E_{field} is the dielectric layer with the highest figure of merit E_{crit}×εᵣ. In other words, the dielectric layer with the highest figure of merit E_{crit}×εᵣ is the strongest layer of the dielectric structure (i.e., the layer with the highest breakdown voltage).

Third, in a polarized capacitor, the cathode appears to be the critical electrode. The direction of the electric field promotes injection of electrons on the cathode side (electrons move towards higher potential). For this reason, placing the strongest dielectric layer of the dielectric structure in front of the cathode allows reducing the electron free circulation.

It follows from the above that placing the dielectric layer with the highest figure of merit E_{crit}×εᵣ in contact with the cathode allows improving the dielectric properties of the dielectric structure. Specifically, it allows reducing the leakage current in the dielectric structure and increases the dielectric strength thereof. This has been confirmed by the inventors' experimental results (which are detailed hereinafter). A higher breakdown voltage and improved reliability of the capacitor follow as a result.

For these reasons, the present disclosure provides an electrical device comprising a capacitor with an improved dielectric structure capable of reliably withstanding high voltages.

In a particular embodiment, at least one of said one or more other layers of the dielectric structure (i.e., a dielectric layer of the dielectric structure not in contact with the cathode) comprises non-stoichiometric silicon-rich silicon nitride.

This embodiment proposes forming the dielectric structure using non-stoichiometric silicon-rich silicon nitride. This material is also referred to as “lower-stress silicon nitride” and noted SiₓN_{y} with x/y>3/4. The use of silicon-rich silicon nitride allows providing a dielectric structure with limited intrinsic mechanical stress. This embodiment is therefore advantageous in that it limits mechanical stress within the capacitive structure, and any negative consequences associated with such stress.

In a particular embodiment, the dielectric layer in contact with the cathode capacitor electrode comprises stoichiometric silicon nitride (Si₃N₄), at least one of said one or more other dielectric layers includes a layer (i.e., a layer of the dielectric structure not in contact with the cathode) comprising non-stoichiometric silicon-rich silicon nitride (SiₓN_{y} with x/y>3/4), and at least one of said one or more other dielectric layers includes a layer (i.e., another layer of the dielectric structure not in contact with the cathode) comprising silicon oxide (SiO₂).

This embodiment is advantageous in that it provides a dielectric structure with a strong adherence to the anode and a limited intrinsic mechanical stress. The use of (thermally grown) silicon oxide SiO₂ allows a strong adherence to the anode (e.g., a silicon substrate comprising protruding walls). And, the use of non-stoichiometric silicon-rich silicon nitride SiₓN_{y} (with x/y>3/4) allows limiting the mechanical stress within the dielectric structure.

This embodiment is also advantageous in that it provides a dielectric structure with a strong dielectric strength and a reduced leakage current. This results from the stacking order of the different layers within the dielectric structure. The dielectric layer comprising stoichiometric silicon nitride (Si₃N₄) is the dielectric layer with the highest figure of merit E_{crit}×εᵣ and is placed in contact with the cathode.

In a particular embodiment, a thickness of the dielectric layer comprising stoichiometric silicon nitride (Si₃N₄) is comprised between 20 nm and 200 nm, a thickness of the dielectric layer comprising non-stoichiometric silicon-rich silicon nitride (SiₓN_{y} with x/y>3/4) is comprised between 500 nm and 1500 nm, and a thickness of the dielectric layer comprising silicon oxide (SiO₂) is comprised between 100 nm and 1000 nm.

The inventors have observed that the dielectric structure provided according to this embodiment is particularly advantageous. The materials and thicknesses used for the various dielectric layers allow providing a dielectric structure with a strong adherence to the anode, a limited intrinsic mechanical stress, and a high breakdown voltage.

In a particular embodiment, an intrinsic mechanical stress of the layer comprising non-stoichiometric silicon-rich silicon nitride (SiₓN_{y} with x/y>3/4) is comprised between 300 MPa and 600 MPa.

According to this embodiment, lower-stress silicon nitride SiₓN_{y} (with x/y>3/4) is used to form the dielectric structure of the capacitor. This allows providing a thick dielectric structure while limiting its intrinsic mechanical stress. In other words, it allows providing a thick dielectric structure while avoiding a deterioration of its electrical properties of the dielectric structure resulting from mechanical stress within the structure. This embodiment is thus advantageous in that it provides a capacitor with a dielectric structure suited for high-voltages applications.

In a particular embodiment, the cathode capacitor electrode comprises (or is formed by) a metal layer, a degenerate semiconductor layer, or a trap-rich layer (e.g., a polysilicon layer).

According to this embodiment, the cathode is made of metals, degenerate semiconductor, or a trap-rich layer (such as a polysilicon layer). In other words, the cathode behaves as a metal. This allows eliminating the non-linear effects associated with semiconductors. In particular, this prevents depletion mechanisms from occurring if the capacitor is used in reverse polarity (i.e., according to the improper polarity).

In a particular embodiment, the anode capacitor electrode or the cathode capacitor electrode comprises a conductive structure having reliefs, such as pores, holes, trenches, or pillars.

This embodiment proposes using a three-dimensional capacitor. That is, a capacitor whose capacitive structure is formed conformally on reliefs such as pores, holes, trenches, or pillars. The use of a three-dimensional capacitor allows providing a large specific area for a given component size. A high capacitance density follows as a result.

According to an example, the anode (or respectively the cathode) comprises a conductive structure formed using a semiconductor substrate with trenches. The dielectric structure extends conformally on the conductive structure, and the cathode (or respectively the anode) extends conformally on the dielectric structure. The use of a semiconductor substrate allows using thick dielectric layers (e.g., by using wide trenches). This provides a capacitor with a high energy storage density and high breakdown voltage, which is particularly suited for high-voltage applications.

According to another example, the anode (or respectively the cathode) comprises a conductive structure formed using an anodic aluminum oxide (AAO) substrate with pores covered by a conductive layer. The dielectric structure extends conformally on the conductive structure, and the cathode (or respectively the anode) extends conformally on the dielectric structure. The use of an AAO substrate with pores allows achieving a high capacitance density. This provides a capacitor with a high energy storage density, which is suited for low-voltage applications.

In a particular embodiment, the electrical device is configured to be used with an operating voltage measured between the anode capacitor electrode and the cathode capacitor electrode exceeding 900 V or 1,200 V, and preferably with an operating voltage comprised between 1,200 V and 1,500 V.

For instance, the proposed electrical device may be used as a decoupling or snubber capacitive element for power electronic.

In another particular embodiment, the electrical device is configured to be used with an operating voltage measured between the anode capacitor electrode and the cathode capacitor electrode comprised between 0.65 V and 10 V.

According to another aspect, the present disclosure also provides an electronic circuit comprising a voltage supply and the proposed electrical device, wherein the anode capacitor electrode of the electrical device is connected to a positive output of the voltage supply and the cathode capacitor electrode of the electrical device is connected to a negative output of the voltage supply.

According to another aspect, the present disclosure provides a method for manufacturing an electrical device, said method comprising: forming a capacitor of the electrical device including: a cathode capacitor electrode, an anode capacitor electrode, and a dielectric structure interposed between the cathode capacitor electrode and the anode capacitor electrode, wherein the dielectric structure comprises a stack of dielectric layers including: a dielectric layer in contact with the cathode capacitor electrode, and one or more other dielectric layers, and wherein a product of a dielectric strength and a permittivity of the dielectric layer in contact with the cathode capacitor electrode is greater than a product of a dielectric strength and a permittivity of each of said one or more other dielectric layers.

The proposed manufacturing method can be adapted to obtain any one of the electrical devices defined in the present disclosure. Further, it should be noted that the embodiments of the proposed method for manufacturing an electrical device present the advantages described in relation with the embodiments of the proposed electrical device.

In a particular embodiment, the proposed method comprises a preliminary step of selecting the dielectric layer in contact with the cathode capacitor electrode such that: the product of the dielectric strength and the permittivity of the dielectric layer in contact with the cathode capacitor electrode is greater than the product of the dielectric strength and the permittivity of each of said one or more other dielectric layers.

In a particular embodiment, the proposed method comprises for each dielectric layer of the dielectric structure: obtaining (determining, evaluating, or computing) the product of the dielectric strength and the permittivity of the dielectric layer.

In a particular embodiment, the product of the dielectric strength and the permittivity of each dielectric layer is obtained based on: a property of a material comprised in this dielectric layer (e.g., a composition of the material, a type of material such as crystalline or polycrystalline), and a thickness of this dielectric layer, and preferably also on a deposition technique used (or intended to be used) for this dielectric layer.

### BRIEF DESCRIPTION OF THE DRAWINGS

Further features and advantages of the present disclosure will become

apparent from the following description of certain embodiments thereof, given by way of illustration only, not limitation, with reference to the accompanying drawings in which:

FIGS. 1 and 2 illustrate cross-section views of an electrical device according to embodiments of the disclosure; and

FIGS. 3 and 4 illustrate experimental results related to the disclosure.

### DETAILED DESCRIPTION OF EXAMPLE EMBODIMENTS

The present disclosure provides an electrical device comprising a capacitor with an improved dielectric structure. More specifically, embodiments of the present disclosure seek to improve the dielectric performance of a multi-layer dielectric structure, in particular by reducing leakage current and increasing the dielectric strength of the dielectric structure.

The present disclosure lies within the particular context of 3D capacitors for high voltage applications. The following description of the disclosure will refer to this particular context, which is only given as an illustrative example and should not limit the disclosure. The disclosure can also be used for applications other than high-voltage applications, and for capacitors other than 3D capacitors.

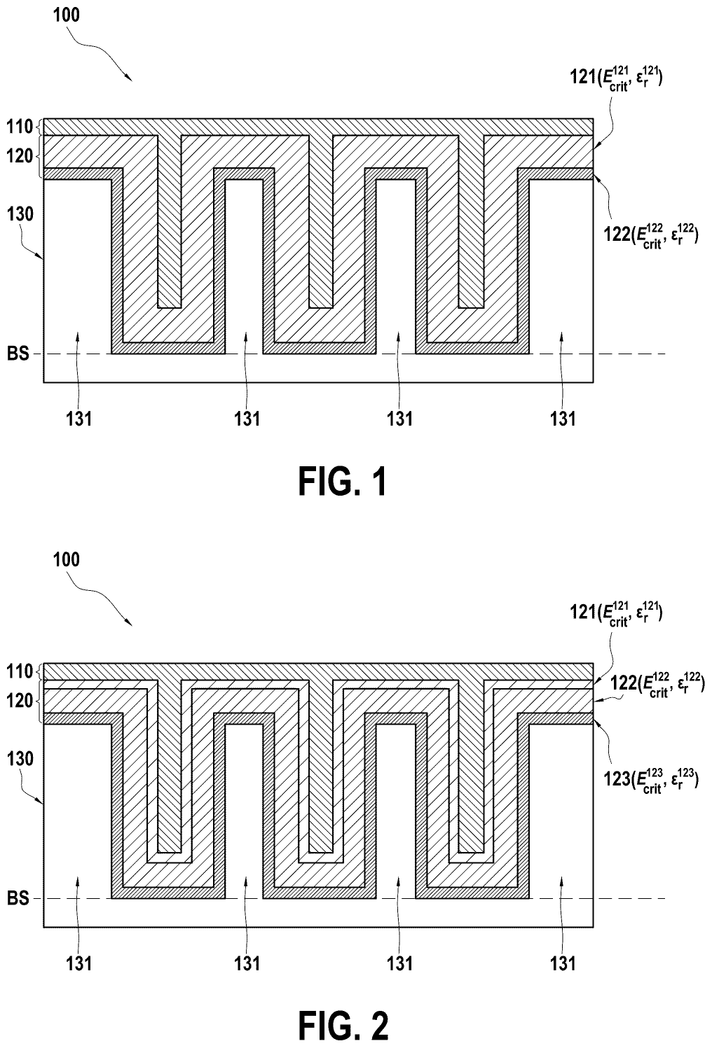

FIG. 1 illustrates a cross-section of an electrical device according to an embodiment of the disclosure. This figure is described hereinafter to introduce the present disclosure.

The electrical device 100 comprises a polarized capacitor formed by a cathode capacitor electrode 110 (here, the top electrode) and an anode capacitor electrode 130 (here, the bottom electrode) separated by a dielectric structure 120.

The bottom electrode 130 comprises a conductive structure with reliefs. Here, the reliefs of the conductive structure are formed by facing walls 131 extending upwards from a base surface BS of the conductive structure.

The conductive structure can be formed by etching a semiconductor substrate (e.g., a doped silicon substrate). The conductive structure could also be formed by a 3D substrate (e.g., an anodic aluminum oxide substrate comprising pores) covered by a conductive layer.

The walls 131 may present: a (substantially) linear shape, or a curved shape, or (substantially) linear shapes joined together by corners. In a particular embodiment, the walls 131 form one or more trenches, for instance, a plurality of separate adjacent trenches or a trench extending in a meander-shape.

The dielectric structure 120 extends conformally over the walls 131 of the bottom electrode 130. It comprises a stack of multiple dielectric layers 121-122 (stacked on each other along the bottom electrode 130 to top electrode 110 direction, the anode-cathode direction).

The top electrode 110 comprises at least one conductive layer (e.g., a layer of polysilicon) extending conformally on the dielectric structure 120.

The top electrode 110 fills the recesses (e.g., the trenches) formed by the walls 131. In other words, the top surface of the top electrode 110 lies above the top surface of the dielectric structure 120 and above the top surface of the walls 131.

This figure illustrates a polarized capacitor in which the top electrode is the cathode 110 and the bottom electrode is the anode 130. However, other embodiments of the disclosure could be envisaged in which the bottom electrode is the cathode and the top electrode is the anode.

Embodiments of the disclosure also relates to an electronic circuit comprising a voltage supply and the proposed electrical device 100, wherein the anode 130 of the electrical device 100 is connected to a positive output of the voltage supply and the cathode 130 of the electrical device 100 is connected to a negative output of the voltage supply.

For instance, the proposed electrical device 100 may be used as a decoupling or snubber capacitive element for power electronic, wherein the operating voltage exceeds 900 V or 1,200 V, and is preferably between 1,200 V and 1,500 V.

For such applications, the capacitor of the electronic device 100 has to be able to reliably withstand high voltages. It is therefore required to have a high breakdown voltage and a high reliability. Meeting these requirements relies in particular on the dielectric properties of the dielectric structure 120 used in the capacitor.

This raises the question of how to select and place the various layers of dielectric structure 120 to improve its dielectric properties and meet these requirements. To answer this question, the inventors have made the developments and observations presented below—points (1) to (4)—which support the present disclosure:
(1) Single dielectric layer: electrical field, leakage current, and breakdown

We first consider a single dielectric layer. For a single layer, the Selbeherr's model links the effective breakdown of a single layer to: (a) the leakage current (i.e., the current density |\vec{Jₙ}| in the equation below) driven by the electrical field E_{field} applied to the layer, and (b) the dielectric strength E_{crit} of the layer.

Further details on this model can be found in S. Selberherr, “On modeling MOS-devices”, Process and device modeling, North-Holland Publishing Co., NLD, 265-299, 1986, and in W. Maes, et al., “Impact ionization in silicon: A review and update”, in Solid-State Electronics, vol. 33, no. 6, pp. 705-718, 1990.

The Selberherr's model characterizes the avalanche in case of breakdown. In this model, the avalanche generation term for electrons is expressed as follows:

$${G}_{n}^{II} = {α}_{n} \cdot \frac{\vert \vec{{J}_{n}} \vert}{q} ,$$

where |\vec{Jₙ}| is the current density, q is the elementary charge, and αₙ is the ionization rate for electrons. The latter is defined by the following expression:

$${α}_{n} = {α}_{n}^{∞} ( T ) \cdot exp ( - {( \frac{{E}_{crit}}{{E}_{field}} )}^{{γ}_{n}} ) .$$

In this equation, the coefficients αₙ^{∞}, T (temperature), and the exponent γₙ are positive real numbers. Here, E_{crit} is the threshold electrical field to activate ionization mechanisms. It varies depending on the material composition and its microstructure. And, E_{field} is the effective electrical field component seen by the charges flowing in the dielectric, expressed by E_{field}=\vec{Eₙ}·\vec{Jₙ}/|\vec{Jₙ}|.

From the above equations, we see that a higher E_{crit}/E_{field} ratio results in a lower ionization rate αₙ and hence a lower avalanche generation term Gₙ^{II}.

Therefore, considering a single dielectric layer, it follows that the dielectric layer achieves a higher breakdown field when the ratio E_{crit}/E_{field} is increased for this dielectric layer.
(2) Multilayer dielectric structure: electrical field division between the dielectric layers

We now consider a dielectric structure comprising a stack of multiple layers, and study the electrical field division between the different layers of the dielectric structure.

To this end, we use an example wherein the dielectric structure comprises a SiO₂ layer and a Si₃N₄ layer.

Setting the electrical field value in the SiO₂ layer to E_{field}^{SiO2}=10 MV/cm, we evaluate the electrical field value in the Si₃N₄ layer. We use the dielectric constant ratio E_{field}^{SiO2}/E_{field}^{Si3N4}=εᵣ^{Si3N4}/εᵣ^{SiO2}. Table 1 in annex outlines the values of εᵣ for thin dielectric layers of SiO₂ and Si₃N₄ (and also for thin dielectric layers of other materials). Based on the values in Table 1, we have εᵣ^{Si3N4}/εᵣ^{SiO2}=1.92. We finally obtain E_{field}^{Si3N4}≃5.2 MV/cm.

We can now determine the E_{crit}/E_{field} ratio for each layer in the dielectric structure. Using the values of Table 1, we have E_{crit}^{Si02}/E_{field}^{Si02}=15/10 and E_{crit}^{Si3N4}/E_{field}^{Si3N4}=7/5.2.

We thus have E_{crit}^{Si02}/E_{field}^{Si02}>E_{crit}^{Si3N4}/E_{field}^{Si3N4}. In other words, the margin between E_{field}^{Si02} and E_{crit}^{Si02} is greater than the margin between E_{field}^{Si3N4} and E_{crit}^{Si3N4}. The Si3N4layer will hence wear out faster than the SiO2 layer. This impacts negatively the reliability and/or the breakdown voltage of the considered bilayer dielectric structure, and thus the reliability and/or the performances of the capacitor.

In fact, for most multilayer dielectric structures, the dielectric strength ratio is not matched with the dielectric constant ratio. Hence, one of the dielectric layers of the dielectric structure wears out faster than the other layers. This negatively impacts the reliability of capacitor.

It can be analytically shown that E_{crit}^{SiO2}×εᵣ^{Si02}>E_{crit}^{Si3N4}×εᵣ^{Si3N4} leads to E_{crit}^{Si02}/E_{field}^{Si02}>E_{crit}^{Si3N4}/E_{field}^{Si3N4}using the dielectric constant ratio E_{field}^{Si02}/E_{field}^{Si3N4}=εᵣ^{Si3N4}/εᵣ^{SiO2}. It means that the SiO2 layer has the highest figure of merit E_{crit}^{SiO2}×εᵣ^{Si02} and therefore the highest ratio E_{crit}^{Si02}/E_{field}^{Si02}. This result is not limited to this particular example, and applies to any material (and/or its deposition method) and any number of layers in the dielectric structure.

Therefore, considering a multilayer dielectric structure, the dielectric layer with the highest figure of merit E_{crit}×εᵣ is also the dielectric layer with the highest ratio E_{crit}/E_{field}.

By combining this result with the conclusion of point (1), it follows that the dielectric layer with the highest figure of merit E_{crit}×εᵣ is the layer of the dielectric structure with the highest breakdown.

We can then conclude that the dielectric layer with the highest figure of merit E_{crit}×εᵣ is the strongest dielectric layer of the multi-layer dielectric structure.
(3) Polarized capacitor: the critical electrode

Following the above points, the next step is to determine where to place the strongest dielectric layer in the dielectric structure to improve the dielectric properties of this structure.

In a polarized capacitor, the cathode appears to be the critical electrode (this is confirmed by the inventor's experimental results detailed below). The direction of the electric field promotes injection of electrons on the cathode side (electrons move towards higher potential). For this reason, the strongest dielectric layer of the dielectric structure is to be placed in front of the cathode to reduce the electron free circulation.
(4) The proposed solution: placing the dielectric layer with the highest figure of merit E_{crit}×εᵣ in contact with the cathode

It follows from the above points (1) to (3) that placing the dielectric layer with the highest figure of merit E_{crit}×εᵣ in contact with the cathode allows improving the dielectric properties of the dielectric structure. Specifically, it allows reducing the leakage current in the dielectric structure and increases the dielectric strength thereof. This has been confirmed by the inventors' experimental results (which are detailed hereinafter). A higher breakdown voltage and improved reliability of the capacitor follow as a result.

The principles of the present disclosure have been outlined above. We now illustrate these principles by describing the example embodiment of the following figure.

FIG. 2 illustrates a cross-section view of an electrical device according to an embodiment of the disclosure.

In contrast to FIG. 1, the electrical device 100 of FIG. 2 comprises a dielectric structure 120 with a stack of three dielectric layers 121, 122, 123 (stacked on each other).

The first dielectric layer 121 in contact with the top electrode 110 (here, the cathode) comprises stoichiometric silicon nitride (Si₃N₄). The thickness of this layer 121 is comprised between 20 nm and 200 nm.

The second dielectric layer 122 comprises non-stoichiometric silicon-rich silicon nitride (SiₓN_{y} with x/y>3/4). The thickness of this layer is comprised between 500 nm and 1500 nm. The mechanical stress of the second dielectric layer 122 is comprised between 300 MPa and 600 MPa. The use of this silicon-rich silicon nitride layer 122 (also referred to as lower-stress silicon nitride) allows providing a dielectric structure 120 with limited intrinsic mechanical stress.

The third dielectric layer 123 extends conformally over (in contact) with the bottom electrode 130 (here, the anode), and comprises silicon oxide (SiO₂). The thickness of this layer is comprised between 100 nm and 1000 nm. This dielectric layer 123 can be formed using thermal oxidation of the conductive structure 110 (e.g., a silicon substrate). The use of this silicon oxide layer 123 allows achieving strong adherence to the bottom electrode 130.

This embodiment is particularly advantageous in that it provides a dielectric structure 120 with a strong adherence to the bottom electrode 130 (comprising the walls 131) and a limited intrinsic mechanical stress.

It should also be emphasized that this embodiment further provides a dielectric structure 120 with a strong dielectric strength and a reduced leakage current. This results from the stacking order of the different dielectric layers 121-123 within the dielectric structure 120.

Following the principles detailed above, the stacking order of the dielectric layers 121-123 is such that: the dielectric layer 121 in contact with the cathode 110 has the highest figure of merit E_{crit}×εᵣ of all the layers in the dielectric structure 120 (i.e., E_{crit}¹²¹×εᵣ¹²¹>E_{crit}¹²²×εᵣ¹²² and E_{crit}¹²¹×εᵣ¹²¹>E_{crit}¹²³×εᵣ¹²³).

Table 2 in annex presents the values of E_{crit}×εᵣ for thick dielectric layers of different materials. Specifically, using the values in this table, we have: E_{crit}^{Si3N4}×εᵣ^{Si3N4}=48.75 greater than E_{crit}^{SixNy}×εᵣ^{SixNy}<48.75 and than E_{crit}^{SiO2}×εᵣ^{SiO2}=35.1.

It should be noted that E_{crit}^{SixNy}×εᵣ^{SixNy} is always lower than E_{crit}^{Si3N4}×εᵣ^{Si3N4}. Since the proportion of nitrogen (N) compared to silicon (Si) is reduced, the mechanical stress and electrical properties of a non-stoichiometric silicon-rich silicon nitride layer (SiₓN_{y}) is reduced compared to a stoichiometric silicon nitride layer (Si₃N₄).

As we detail below, the inventors' experimental results confirm that the proposed dielectric structure 120 presents an increased dielectric strength and a reduced leakage current.

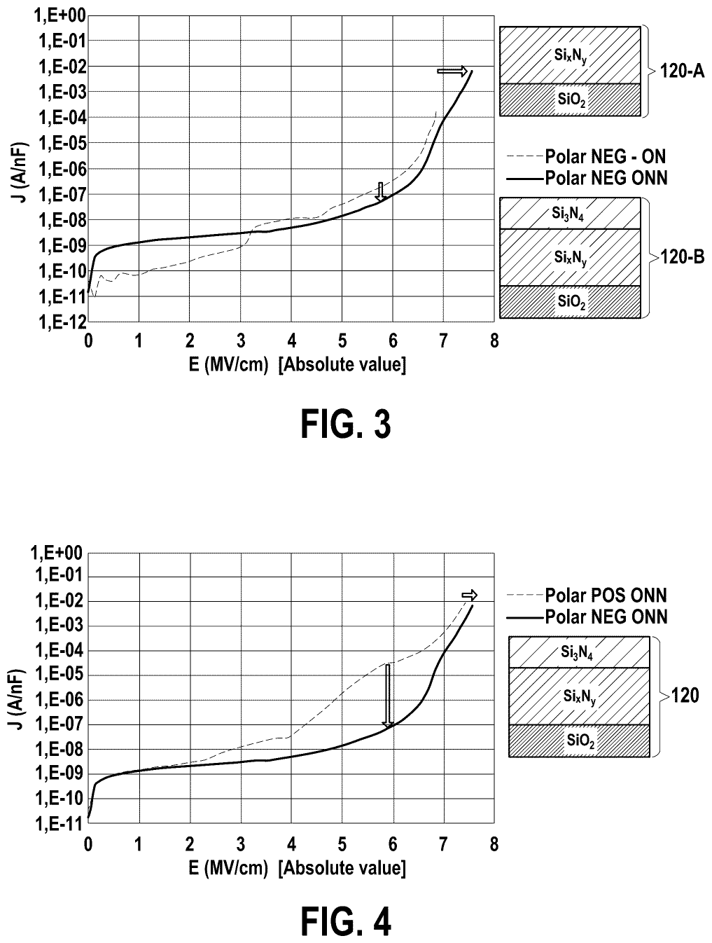

FIG. 3 illustrates experimental results related to the disclosure. This figure compares the dielectric performance of a bilayer dielectric structure (dashed line) and a trilayer dielectric structure (solid line).

More precisely, the plot on this figure shows the current density J in the dielectric structure as a function of the electrical field E applied to it (for the bilayer and trilayer dielectric structures).

The bilayer dielectric structure 120-A (dashed line) is formed by a stack of a silicon oxide (SiO₂) layer and a non-stoichiometric silicon-rich silicon nitride (SiₓN_{y}) layer. The trilayer dielectric structure 120-B (solid line) further comprises a stoichiometric silicon nitride (Si₃N₄) layer with a thickness of 50 nm. This Si₃N₄ layer has the highest figure of merit E_{crit}×εᵣ and is placed between the cathode and the SiₓN_{y} layer.

As shown in FIG. 3, the introduction of a thin layer of silicon nitride in front of the cathode provides the following advantages. First, it reduces the current density within the dielectric structure at high electrical field values (as indicated by the vertical arrow in this figure). Second, it increases the dielectric strength of the dielectric structure by approximatively 10% (as indicated by the horizontal arrow).

The proposed solution thus provides a dielectric structure with higher dielectric strength and reduced leakage current, i.e., with improved dielectric performance. It follows that the capacitor using this dielectric structure presents an increased breakdown voltage and improved reliability.

The advantages of the proposed solution are further corroborated by the experimental results shown in the following figure.

FIG. 4 illustrates experimental results related to the disclosure. This figure compares the dielectric performance of a trilayer dielectric structure according to different polarities.

The plot on this figure shows the current density J in the dielectric structure as a function of the electrical field E applied to it (for the different polarities).

The trilayer dielectric structure 120 is formed by a stack of a silicon oxide (SiO₂) layer, a non-stoichiometric silicon-rich silicon nitride (SiₓN_{y}) layer, and a stoichiometric silicon nitride (Si₃N₄) layer. The Si₃N₄ layer presents the highest figure of merit E_{crit}×εᵣ.

In the first polarity (noted POS and in dashed line on this figure), the Si₃N₄ layer is placed in front of the anode. And, in the second polarity (noted NEG and in solid line on this figure), the Si₃N₄ layer is placed in front of the cathode.

As shown in this FIG. 4, placing the layer with the highest figure of merit E_{crit}×εᵣ in front of the cathode provides the following advantages. First, it significantly reduces the current density in the dielectric structure (as indicated by the vertical arrow in this figure). The current density is reduced by more than 100 times for electric field values between 5 and 6 MV/m (corresponding to the electrical field values of the envisaged applications). Second, it also increases the dielectric strength of the dielectric structure (as indicated by the horizontal arrow in this figure).

The experimental results in this figure confirm that the cathode is the critical electrode in a polarized capacitor. They also demonstrate that placing the layer with the highest figure of merit E_{crit}×εᵣ in front of the cathode improves the dielectric performance of the dielectric structure.

Additional Variants: Although the present disclosure has been described above with reference to certain specific embodiments, it will be understood that the disclosure is not limited by the particularities of these specific embodiments. Numerous variations, modifications, and developments may be made in the above-described embodiments within the scope of the claims.

In particular, the present disclosure has been described in reference to a capacitor with a 3D capacitive structure and intended for high-voltage applications. However, other embodiments of the present disclosure could be envisaged, for instance, embodiments in which the capacitor has a planar capacitive structure or is intended for applications other than high voltage applications.

It is to be understood that references in this text to directions and locations, such as “top” and “bottom”, “front” and “rear”, merely refer to the directions that apply when architectures and components are oriented as illustrated in the accompanying drawings.

### ANNEXES

TABLE 1
properties of various materials that can be used for the
dielectric structure considering thin films (thickness
between 1 nm and 20 nm, or between 1 nm and 100 m)

| Material | εᵣ | E_{crit} | Ecrit × εᵣ |
|---|---|---|---|
| SiO₂ (Thermal) | 3.9 | 15 | 58.5 |
| Si₃N₄ (LPCVD) | 7.5 | 7 | 52.5 |
| SiₓN_{y} x/y > ¾ (LPCVD) | ~7.5 | <7 | <52.5 |
| Al₂O₃ (ALD) | 8.8 | 10 | 88 |
| SiON (LPCVD) | ≥4.6 | 13-15 | ~70 |

TABLE 2
properties of various materials that can be used for the
dielectric structure considering thick films (thickness
greater than 500 nm, or even 1,000 nm)

| Material | εᵣ | E_{crit} | Ecrit × εᵣ |
|---|---|---|---|
| SiO₂ (Thermal) | 3.9 | 9 | 35.1 |
| Si₃N₄ (LPCVD) | 7.5 | 6.5 | 48.75 |
| SiₓN_{y} x/y > ¾ (LPCVD) | ~7.5 | <6.5 | <48.75 |
| Al₂O₃ (ALD) | N/A | | |
| SiON (LPCVD) | ≥4.6 | 11 | 50.6 |

1. An electrical device comprising a capacitor including: a cathode capacitor electrode, an anode capacitor electrode, and a dielectric structure interposed between the cathode capacitor electrode and the anode capacitor electrode,
wherein the dielectric structure comprises a stack of dielectric layers including: a dielectric layer in contact with the cathode capacitor electrode, and one or more other dielectric layers, and
wherein a product of a dielectric strength (E_{crit}¹²¹) and a permittivity (εᵣ¹²¹) of the dielectric layer in contact with the cathode capacitor electrode is greater than a product of a dielectric strength (E_{crit}¹²², E_{crit}¹²³) and a permittivity (εᵣ¹²², εᵣ¹²³) of each of said one or more other dielectric layers.

2. The electrical device according to claim 1, wherein at least one of said one or more other layers of the dielectric structure comprises non-stoichiometric silicon-rich silicon nitride.

3. The electrical device according to claim 2, wherein:
the dielectric layer in contact with the cathode capacitor electrode comprises stoichiometric silicon nitride,
at least one of said one or more other dielectric layers includes a layer comprising non-stoichiometric silicon-rich silicon nitride, and
at least one of said one or more other dielectric layers includes a layer comprising silicon oxide.

4. The electrical device according to claim 3, wherein:
a thickness of the dielectric layer comprising stoichiometric silicon nitride is between 20 nm and 200 nm,
a thickness of the dielectric layer comprising non-stoichiometric silicon-rich silicon nitride is between 500 nm and 1500 nm, and
a thickness of the dielectric layer comprising silicon oxide is between 100 nm and 1000 nm.

5. The electrical device according to claim 2, wherein an intrinsic mechanical stress of the layer comprising non-stoichiometric silicon-rich silicon nitride is between 300 MPa and 600 MPa.

6. The electrical device according to claim 1, wherein the cathode capacitor electrode comprises a metal layer, or a degenerate semiconductor layer, or a trap-rich layer.

7. The electrical device according to claim 1, wherein the anode capacitor electrode or the cathode capacitor electrode comprises a conductive structure having reliefs.

8. The electrical device according to claim 7, wherein the reliefs are pores, holes, trenches, or pillars.

9. The electrical device according to claim 1, wherein the electrical device is configured to be used with an operating voltage measured between the anode capacitor electrode and the cathode capacitor electrode exceeding 900 V or 1200 V.

10. The electrical device according to claim 1, wherein the electrical device is configured to be used with an operating voltage measured between the anode capacitor electrode and the cathode capacitor electrode between 1200 V and 1500 V.

11. The electrical device according to claim 1, wherein the electrical device is configured to be used with an operating voltage measured between the anode capacitor electrode and the cathode capacitor electrode of between 0.65 V and 10 V.

12. An electronic circuit comprising a voltage supply and the electrical device according to claim 1, wherein the anode capacitor electrode of the electrical device is connected to a positive output of the voltage supply and the cathode capacitor electrode of the electrical device is connected to a negative output of the voltage supply.

13. A method for manufacturing an electrical device, said method comprising:
forming a capacitor of the electrical device including: a cathode capacitor electrode, an anode capacitor electrode, and a dielectric structure interposed between the cathode capacitor electrode and the anode capacitor electrode,
wherein the dielectric structure comprises a stack of dielectric layers including: a dielectric layer in contact with the cathode capacitor electrode, and one or more other dielectric layers, and
wherein a product of a dielectric strength (E_{crit}¹²¹) and a permittivity (εᵣ¹²¹) of the dielectric layer in contact with the cathode capacitor electrode is greater than a product of a dielectric strength (E_{crit}¹²², E_{crit}¹²³) and a permittivity (εᵣ¹²², εᵣ¹²³) of each of said one or more other dielectric layers.

14. The method according to claim 13, comprising a preliminary step of selecting the dielectric layer in contact with the cathode capacitor electrode such that:
the product of the dielectric strength (E_{crit}¹²¹) and the permittivity (εᵣ¹²¹) of the dielectric layer in contact with the cathode capacitor electrode is greater than the product of the dielectric strength (E_{crit}¹²², E_{crit}¹²³) and the permittivity (εᵣ¹²², εᵣ¹²³) of each of said one or more other dielectric layers.

15. The method according to claim 14, further comprising, for each dielectric layer of the dielectric structure: obtaining the product of the dielectric strength (E_{crit}¹²¹-E_{crit}¹²³) and the permittivity (εᵣ¹²¹-εᵣ¹²³) of the dielectric layer.

16. The method according to claim 15, wherein the product of the dielectric strength (E_{crit}¹²¹-E_{crit}¹²³) and the permittivity (εᵣ¹²¹-εᵣ¹²³) of each dielectric layer is obtained based on:
a property of a material comprised in this dielectric layer, and
a thickness of this dielectric layer, and
preferably also on a deposition technique used for this dielectric layer.

17. The method according to claim 16, wherein the product of the dielectric strength (E_{crit}¹²¹-E_{crit}¹²³) and the permittivity (εᵣ¹²¹-εᵣ¹²³) of each dielectric layer is also obtained based on a deposition technique used for this dielectric layer.
